(19) United States
(12) Patent Application Publication
(10) Pub. No.: US 2025/0393352 A1
(43) Pub. Date: Dec. 25, 2025

(54) APPARATUS FOR MANUFACTURING DISPLAY DEVICE AND METHOD OF MANUFACTURING DISPLAY DEVICE

(71) Applicant: Samsung Display Co., LTD., Yongin-si (KR)

(72) Inventors: Jong Hyuk KANG, Yongin-si (KR); Buem Joon KIM, Yongin-si (KR); Won Ho LEE, Yongin-si (KR)

(73) Assignee: Samsung Display Co., LTD., Yongin-si (KR)

(21) Appl. No.: 18/978,589

(22) Filed: Dec. 12, 2024

(30) Foreign Application Priority Data
Mar. 26, 2024 (KR) 10-2024-0041261

(51) Int. Cl. H10H 29/03; H01L 21/67; H01L 21/673; H10H 29/01

(52) U.S. Cl. CPC H10H 29/03; H01L 21/67103; H01L 21/6715; H01L 21/67326; H10H 29/012

(57) ABSTRACT

An apparatus for manufacturing a display device includes a chamber, a stage supporting a target substrate, an electric field application module disposed at a side of the stage, a heating element overlapping the stage in a plan view, a heat source part that moves in a direction parallel to a plane the stage extends on the stage, and a vacuum pump connected to the chamber.

### CROSS-REFERENCE TO RELATED APPLICATION(S)

This application claims priority to and benefits of Korean patent application No. 10-2024-0041261 under 35 U.S.C. § 119(a), filed on Mar. 26, 2024, in the Korean Intellectual Property Office (KIPO), the entire contents of which are incorporated herein by reference.

### BACKGROUND

### 1. Technical Field

The disclosure generally relates to an apparatus for manufacturing a display device and a method of manufacturing a display device.

### 2. Description of the Related Art

With the development of information technologies, the importance of a display device which is a connection medium between a user and information increases. Accordingly, research and development of display devices have been continuously conducted.

A display device may include a small inorganic light emitting element to a degree of micro scale or nano scale. The inorganic light emitting element may be disposed on a substrate, and be aligned as an electrical field is formed on the substrate. When the inorganic light emitting element is not properly aligned, it may be difficult for the display device to have sufficient luminance, and reliability of the display device may deteriorate.

### SUMMARY

Embodiments provide an apparatus for manufacturing a display device and a method of manufacturing a display device, which can improve an alignment degree of light emitting elements.

In accordance with an embodiment of the disclosure, an apparatus for manufacturing a display device may include a chamber, a stage supporting a target substrate, an electric field application module disposed at a side of the stage, a heating element overlapping the stage in a plan view, a heat source part that moves in a direction parallel to a plane the stage extends on the stage, and a vacuum pump connected to the chamber.

The apparatus may further include a printing part that sprays an ink including at least one light emitting element onto the target substrate. The electric field application module may form an electric field on the target substrate, such that the at least one light emitting element may be aligned on the target substrate.

The stage may include an internal space in which the heating element is disposed. The heating element may be disposed in the internal space.

The heating element may include a hot plate.

The heating element may include a heat source having a temperature in a range of about 20° C. to about 60° C.

The heat source part may include a bar-shaped heat source extending in a first direction. The heat source part may move in the direction other than the first direction.

The heat source part may move on the stage between a first time and a second time after the first time. At the first time, the heat source part may overlap a first side of the stage in a plan view, and may not overlap a second side of the stage in a plan view.

At the second time, the heat source part may not overlap the first side of the stage in a plan view, and may overlap the second side of the stage in a plan view.

The heat source part may include a first heat source part and a second heat source part. The first heat source part and the second heat source part may move on the stage between a first time and a second time after the first time. At the first time, the first heat source part may overlap a first side of the stage in a plan view. At the first time, the second heat source part may overlap a second side of the stage in a plan view.

The heat source part may include a first heat source part and a second heat source part. The first heat source part and the second heat source part may move on the stage between a first time and a second time after the first time. At the first time, the first heat source part may overlap an end portion of the stage in a plan view. At the first time, the second heat source part may overlap a central area of the stage in a plan view. Between the first time and the second time, the first heat source part and the second heat source part may move in a same direction.

The heat source part may be disposed in the chamber.

The heat source part may include a heat source having a temperature in a range of about 60° C. to about 200° C.

The vacuum pump may be connected to the chamber through an exhaust line. At least one of a pressure control valve and a flow control valve may be installed on the exhaust line. The vacuum pump may form a vacuum pressure atmosphere in the chamber.

The electric field application module may include a probe support and a probe unit, which are disposed on the stage. The probe unit may include a probe driver, a probe jig disposed at the probe driver such that an electrical signal is transferred to the probe jig, and a probe pad transferring the electrical signal to the target substrate. The probe driver may move the probe jig in a horizontal direction and a vertical direction.

The ink may further include a solvent.

In accordance with an embodiment of the disclosure, a method of manufacturing a display device may include spraying an ink including at least one light emitting element and a solvent onto a target substrate, aligning the at least one light emitting element on the target substrate, and drying at least a portion of the solvent. The aligning of the at least one light emitting element may include forming an electric field on the top of the target substrate, and controlling a temperature of the target substrate. The drying of the at least a portion of the solvent may include moving a heat source part on the target substrate The aligning of the at least one light emitting element and the drying of the at least a portion of the solvent may be performed in a chamber.

The forming of the electric field on the top of the target substrate and the controlling of the temperature of the target substrate may be simultaneously performed. The controlling of the temperature of the target substrate may include applying heat to the target substrate, using a heating element.

The moving of the heat source part may include allowing the heat source part to reciprocate along a direction parallel to a plane the target substrate extends on the target substrate. The heat source part may include a bar-shaped heat source extending in a first direction.

The drying of the at least a portion of the solvent may include forming an internal space of the chamber to be in a vacuum state as a vacuum pump is connected to the chamber.

The forming of the electric field on the target substrate may include forming an electric field, using a probe unit. The probe unit may include a probe driver, a probe jig disposed at the probe driver such that an electrical signal is transferred to the probe jig, and a probe pad transferring the electrical signal to the target substrate. The probe driver may move the probe jig in a horizontal direction and a vertical direction.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be more thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic plan view illustrating a display device in accordance with an embodiment of the disclosure.

FIG. 2 is a schematic perspective view illustrating a light emitting element in accordance with an embodiment of the disclosure.

FIG. 3 is a schematic block diagram illustrating an apparatus for manufacturing a display device in accordance with an embodiment of the disclosure.

FIG. 4 is a schematic plan view of the apparatus shown in FIG. 3.

FIG. 5 is a schematic cross-sectional view illustrating an operation of an inkjet printing apparatus in accordance with an embodiment of the disclosure.

FIGS. 6 and 7 are schematic cross-sectional views illustrating an operation of an electric field application module in accordance with an embodiment of the disclosure.

FIG. 8 is a schematic cross-sectional view illustrating an operation of a heat source part in accordance with an embodiment of the disclosure.

FIG. 9 is a schematic plan view of a heat source part in accordance with an embodiment of the disclosure.

FIG. 10 is a schematic cross-sectional view illustrating an apparatus for manufacturing a display device in accordance with an embodiment of the disclosure.

FIG. 11 is a schematic cross-sectional view illustrating an apparatus for manufacturing a display device in accordance with an embodiment of the disclosure.

FIG. 12 is a flowchart illustrating a method of manufacturing a display device.

FIGS. 13 to 15 are schematic cross-sectional views illustrating processes of manufacturing a display device.

### DETAILED DESCRIPTION OF THE EMBODIMENTS

The disclosure may apply various changes and different shape, therefore only illustrate in details with particular examples. However, the examples do not limit to certain shapes but apply to all the change and equivalent material and replacement. The drawings included are illustrated a fashion where the figures are expanded for the better understanding.

It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the teachings of the disclosure. As used herein, the singular forms are intended to include the plural forms as well, unless the context clearly indicates otherwise.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

The disclosure generally relates to an apparatus for manufacturing a display device and a method of manufacturing a display device. Hereinafter, an apparatus for manufacturing a display device and a method of manufacturing a display device in accordance with an embodiment of the disclosure will be described with reference to the accompanying drawings.

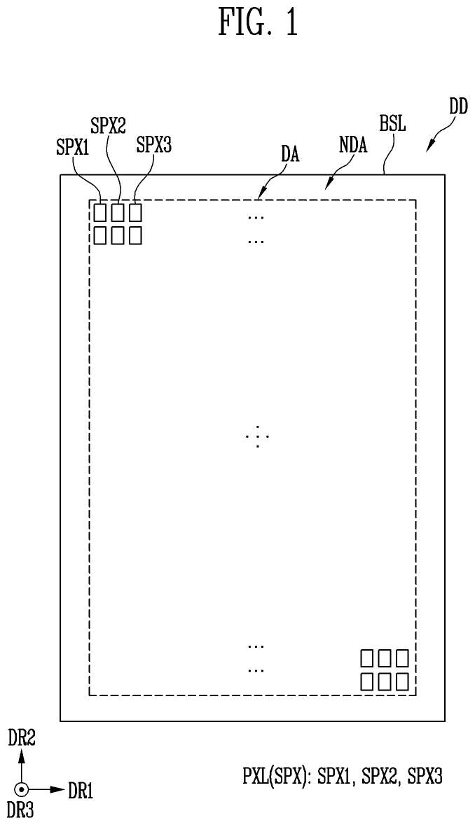

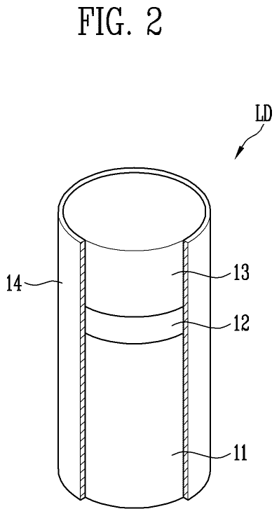

FIG. 1 is a schematic plan view illustrating a display device in accordance with an embodiment of the disclosure. FIG. 2 is a schematic perspective view illustrating a light emitting element in accordance with an embodiment of the disclosure.

Referring to FIG. 1, the display device DD may be configured to emit light. The display device DD may include a light emitting element LD (see FIG. 2). In an embodiment, the display device DD may display moving images or still images. The display device DD may be used as a display screen of not only portable electronic devices such as a mobile phone, a smart phone, a tablet personal computer (PC), a mobile communication terminal, an electronic notebook, an electronic book, a portable multimedia player (PMP), a navigation system, and an ultra-mobile PC, but also various products such as a television, a notebook computer, a monitor, an advertisement board, and Internet of things (IOT). However, the application field of the display device DD is not limited to a specific example.

The display device DD may be formed in a rectangular shape in a plan view having short sides in a first direction DR1 and long sides in a second direction DR2 intersecting the first direction DR1. A corner at which the short side in the first direction DR1 and the long side in the second direction DR2 meet each other may be formed round to have a curvature or be formed at a right angle. The shape of the display device DD is not limited to a quadrangular shape, and the display device DD may be formed in another polygonal shape or a round shape such as a circular shape or an elliptical shape. The display device DD may be formed flat, but the disclosure is not limited thereto. For example, the display device DD may include a curved portion which is formed at left/right ends and has a constant curvature or a changing curvature. In an embodiment, the display device DD may be formed flexible enough to be warpable, curvable, bendable, foldable or rollable. For example, the display device DD may be a flexible display device.

In the disclosure, the first direction DR1 may be a horizontal direction as a row direction of pixels PXL. The second direction DR2 may be a column (or vertical) direction of pixels PXL. A third direction DR3 may be a display direction of the display device DD or a normal direction of a plane on which a base layer BSL is disposed.

The display device DD may include a display area DA and a non-display area NDA. The non-display area NDA may be an area other than the display area DA. The non-display area NDA may surround at least a portion of the display area DA in a plan view.

The display area DA may be an area in which pixels PXL are disposed. The non-display area NDA may be an area in which the pixels PXL are not disposed. A driving circuit, lines, and pads, which are connected to the pixels PXL of the display area DA, may be disposed in the non-display area NDA.

In an embodiment, the pixel PXL (or sub-pixels SPX) may include a first sub-pixel SPX1, a second sub-pixel SPX2, and a third sub-pixel SPX3. At least one first sub-pixel SPX1, at least one second sub-pixel SPX2, and at least one third sub-pixel SPX3 may form one pixel unit capable of emitting lights of various colors. In FIG. 1, it is illustrated that each pixel PXL includes three sub-pixels SPX1, SPX2, and SPX3, i.e., the first sub-pixel SPX1, the second sub-pixel SPX2, and the third sub-pixel SPX3. However, the disclosure is not limited thereto.

In an embodiment, the pixels PXL (or sub-pixels SPX) may be arranged according to a stripe arrangement structure, a PENTILE™ arrangement structure, or the like. However, the disclosure is not necessarily limited thereto.

The first sub-pixel SPX1 may emit first light, the second sub-pixel SPX2 may emit second light, and the third sub-pixel SPX3 may emit third light. The first light may be light in a red wavelength band, the second light may be light in a green wavelength band, and the third light may be light in a blue wavelength band. The red wavelength band may be a wavelength band in a range of about 600 nm to about 750 nm, the green wavelength band may be a wavelength band in a range of about 480 nm to about 560 nm, and the blue wavelength band may be a wavelength band in a range of about 370 nm to about 460 nm. However, the disclosure is not limited thereto.

Each of the first sub-pixel SPX1, the second sub-pixel SPX2, and the third sub-pixel SPX3 may include an inorganic light emitting element including an inorganic semiconductor as the light emitting element LD emitting light. Hereinafter, the inorganic light emitting element which each of the first sub-pixel SPX1, the second sub-pixel SPX2, and the third sub-pixel SPX3 includes will be described with reference to FIG. 2.

In FIG. 2, a rod-type light emitting element having a cylindrical shape is illustrated as an embodiment of the light emitting element LD. However, the kind and shape of the light emitting element LD are not limited thereto.

The light emitting element LD may include a first conductivity type semiconductor layer 11, a second conductivity type semiconductor layer 13, and an active layer 12 interposed between the first and second conductivity type semiconductor layers 11 and 13. In an embodiment, the light emitting element LD may be configured as a stack structure in which the first conductivity type semiconductor layer 11, the active layer 12, and the second conductivity type semiconductor layer 13 are sequentially stacked.

In an embodiment, the light emitting element LD may be provided in a rod shape extending in a direction. In case that an extending direction of the light emitting element LD is a length direction, the light emitting element LD may have an end portion and another end portion in the length direction.

In an embodiment, one of the first and second conductivity type semiconductor layers 11 and 13 may be disposed at the end portion of the light emitting element LD, and another one of the first and second conductivity type semiconductor layers 11 and 13 may be disposed at the another end portion of the light emitting element LD.

The light emitting element LD in accordance with an embodiment of the disclosure may be an inorganic light emitting element. In an embodiment, the light emitting element LD may be manufactured in a rod shape. The “rod shape” may include a rod-like shape or a bar-like shape, which is long in its length direction (e.g., its aspect ratio is greater than 1), such as a circular pillar or a polygonal pillar, and the cross-sectional shape is not particularly limited. For example, a length of the light emitting element LD may be greater than a diameter (or a width of a section) of the light emitting element LD. However, the disclosure is not limited thereto.

In an embodiment, the light emitting element LD may have a diameter and a length, which are small to a degree of, for example, micro scale or nano scale. However, the size of the light emitting element LD is not limited thereto. For example, the size of the light emitting element LD may be variously changed according to design conditions of a light emitting display device to which the light emitting element LD is applied.

The first conductivity type semiconductor layer 11 may include, for example, at least one n-type semiconductor layer. For example, the first conductivity type semiconductor layer 11 may include at least one of InAlGaN, GaN, AlGaN, InGaN, AlN, and InN, and doped with a first conductive dopant such as Si, Ge or Sn. However, the material constituting the first conductivity type semiconductor layer 11 is not limited thereto. For example, various materials may constitute the first conductivity type semiconductor layer 11.

The active layer 12 may be disposed on the first conductivity type semiconductor layer 11, and be formed in a single-quantum well structure or a multi-quantum well structure. In an embodiment, a clad layer (not shown) doped with a conductive dopant may be formed in at least one of upper and lower portions of the active layer 12. In an embodiment, the clad layer may be formed of an AlGaN layer or an InAlGaN layer. In an embodiment, a material such as AlGaN or AlInGaN may be used to form the active layer 12. However, the disclosure is not limited thereto, and various materials may constitute the active layer 12.

In case that an electric force having a voltage or higher is applied to both end portions of the light emitting element LD, the light emitting element LD may emit light as electron-hole pairs are combined in the active layer 12. The light emission of the light emitting element LD may be controlled by using such a principle, so that the light emitting element LD may be used as a light source for a pixel.

The second conductivity type semiconductor layer 13 may be disposed on the active layer 12, and include a semiconductor layer having a type different from the type of the first conductivity type semiconductor layer 11. In an embodiment, the second conductivity type semiconductor layer 13 may include at least one p-type semiconductor layer. For example, the second conductivity type semiconductor layer 13 may include at least one of InAlGaN, GaN, AlGaN, InGaN, AlN, and InN, and doped with a second conductive dopant such as Mg. However, the material constituting the second conductivity type semiconductor layer 13 is not limited thereto. For example, various materials may constitute the second conductivity type semiconductor layer 13.

In an embodiment, the light emitting element LD may further include an additional component in addition to the first conductivity type semiconductor layer 11, the active layer 12, and the second conductivity type semiconductor layer 13, which are described above. In an embodiment, the light emitting element LD may additionally include at least one of one or more phosphor layers, one or more active layers, one or more semiconductor layers, and one or more electrode layers, which are disposed at upper or lower portions of the first conductivity type semiconductor layer 11, the active layer 12, and the second conductivity type semiconductor layer 13.

In an embodiment, the light emitting element LD may further include an insulative film 14. In an embodiment, the insulative film 14 may be formed to surround at least a portion of an outer circumferential surface of the active layer 12. In an embodiment, the insulative film 14 may further surround at least a portion of the first and second conductivity type semiconductor layers 11 and 13.

In an embodiment, the insulative film 14 may include a transparent insulating material. For example, the insulative film 14 may include at least one of silicon oxide (SiOₓ) (e.g., SiO₂), silicon nitride (SiNₓ) (e.g., Si₃N₄), aluminum oxide (AlₓO_{y}) (e.g., Al₂O₃), titanium oxide (TiₓO_{y}) (e.g., TiO₂), and hafnium oxide (HfOₓ), or another insulating material.

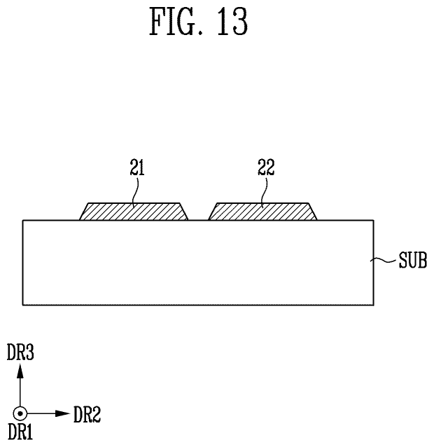

The insulative film 14 may prevent the active layer 12 of the light emitting element LD from being short-circuited with first and second electrodes 21 and 22 (see FIG. 13), or the like. Accordingly, the electrical stability of the light emitting element LD may be ensured.

The light emitting element LD may be used as a light source in various types of display devices DD including a light emitting display panel. In an embodiment, at least one light emitting element LD may be disposed in each pixel area of the light emitting display panel, and accordingly, a light emitting unit of each pixel may be configured. However, the application field of the light emitting element LD is not limited to display devices. For example, the light emitting element LD may be used for other types of light emitting devices which require a light source such as a lighting device.

The light emitting element LD may be aligned based on an electric field formed on the base layer BSL, and accordingly, the display device DD may be manufactured.

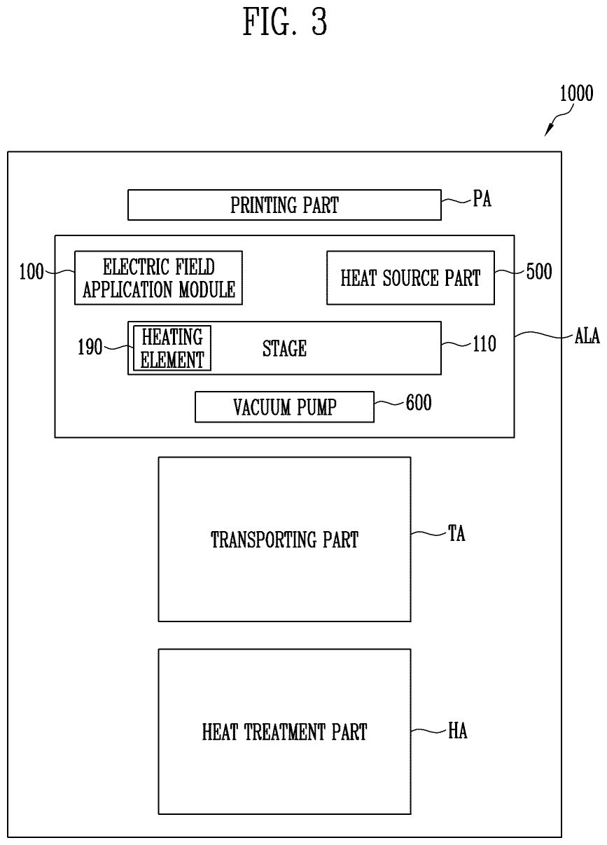

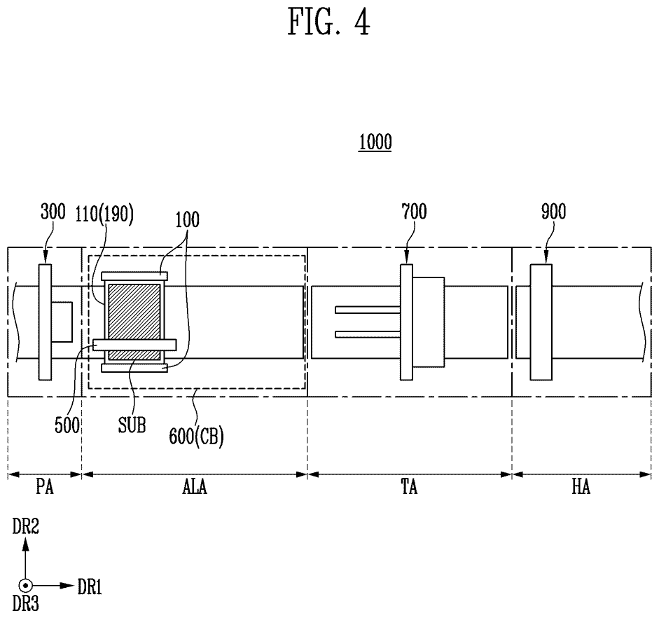

Hereinafter, an apparatus 1000 of manufacturing a display device, which can align the light emitting element LD to manufacture the display device, will be described with reference to FIGS. 3 and 4.

FIG. 3 is a schematic block diagram illustrating an apparatus for manufacturing a display device in accordance with an embodiment of the disclosure. FIG. 4 is a schematic plan view of the apparatus shown in FIG. 3. FIGS. 3 and 4 illustrate a schematic block diagram and an arrangement relationship of components of the apparatus 1000. FIGS. 3 and 4 may be views schematically illustrating an arrangement relationship of components of the apparatus 1000. However, this is merely an embodiment, and the configuration and arrangement relationship of the apparatus 1000 are not limited thereto.

In the apparatus 1000 in accordance with an embodiment of the disclosure, an ink including light emitting elements LD and a solvent in which the light emitting elements LD are dispersed may be spray onto a target substrate, and the light emitting elements LD may be aligned by forming an electric field on the target substrate. In an embodiment, the light emitting elements LD may be mounted on the target substrate by removing at least a portion of the solvent sprayed on the target substrate.

According to the apparatus 1000 in accordance with an embodiment of the disclosure, a process of aligning the light emitting elements LD and a process of removing at least a portion of the solvent sprayed onto the target substrate may be performed in a same chamber CB (see FIG. 4), and the alignment degree of the light emitting elements LD may be improved.

Referring to FIGS. 3 and 4, the apparatus 1000 in accordance with an embodiment of the disclosure may include a printing part PA, an alignment part ALA, a transporting part TA, and a heat treatment part HA. However, the disclosure is not limited thereto.

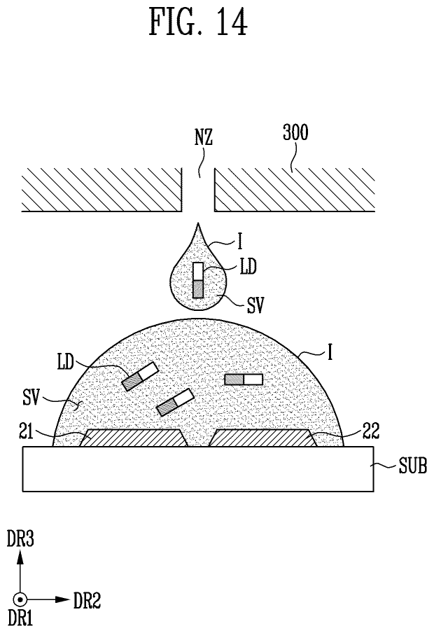

The printing part PA may include an apparatus and an area, which can perform a process of spraying, onto a target substrate SUB, an ink I (see FIG. 14) including light emitting elements LD and a solvent SV (see FIG. 14) in which the light emitting elements LD are dispersed. The printing part PA may include an area in which a printing process of spraying the ink I onto the target substrate SUB is performed.

The target substrate SUB may be a member on which the light emitting elements LD are disposed to form the display device DD, and may be a member including a pixel circuit and the like. The target substrate SUB may form a base to which the light emitting elements LD are supplied. In an embodiment, the target substrate SUB may be a mother substrate, and correspond to the base layer BSL of the display device DD in FIG. 1. The target substrate SUB may be a backplane layer.

The alignment part ALA may include an apparatus and an area, which can perform a process of aligning the light emitting elements LD included in the solvent SV and removing (e.g., drying) at least a portion of the solvent SV. The alignment part ALA may include an apparatus and an area, which can perform a process of removing at least a portion of the solvent SV while aligning the light emitting elements LD sprayed from the printing part PA. The alignment part ALA may simultaneously perform an alignment operation of aligning the light emitting elements LD and a drying operation of drying at least a portion of the solvent SV in advance.

The heat treatment part HA may be disposed to be spaced apart from the alignment part ALA. The heat treatment part HA may include an apparatus and an area, which can perform a process of irradiating heat onto the target substrate SUB onto which the ink I is sprayed. The heat treatment part HA may irradiate heat onto the target substrate SUB on which the ink I is sprayed. The heat provided by the heat treatment part HA may remove another portion of the solvent SV which is not removed on the target substrate SUB.

The transporting part TA may be disposed between the alignment part ALA and the heat treatment part HA. The transporting part TA may include an apparatus for transporting the target substrate SUB and an area in which the target substrate SUB is transported. The transporting part TA may be an area in which the target substrate SUB is moved from the alignment part ALA to the heat treatment part HA after the printing process of spraying the ink I onto the target substrate SUB is performed.

The light emitting elements LD sprayed onto the target substrate SUB may be aligned through an alignment process. For example, the alignment process of the light emitting elements LD may be performed in the alignment part ALA, and the light emitting elements LD may be aligned on the target substrate SUB. In an embodiment, the alignment process of the light emitting elements LD be performed only in the alignment part ALA, but the disclosure is not necessarily limited thereto. For example, the alignment process of the light emitting elements LD may be further performed in at least one area of the printing part PA, the heat treatment part HA, and the transporting part TA.

The apparatus 1000 in accordance with an embodiment of the disclosure may include an inkjet printing apparatus 300, a heat source part 500, a vacuum pump 600, a stage 110, a heating element 190, and an electric field application module 100. The apparatus 1000 may further include a transporting unit 700 and a heat treatment apparatus 900.

The inkjet printing apparatus 300 may be disposed in the printing part PA. The inkjet printing apparatus 300 may be disposed in the printing part PA, to provide (e.g., spray) the ink I onto the target substrate SUB.

In an embodiment, the inkjet printing apparatus 300 and the alignment part ALA may be disposed in different areas. For example, the inkjet printing apparatus 300 may be disposed outside a chamber CB in which the alignment part ALA is disposed. The chamber CB may be an area in which the alignment process of the light emitting elements LD is performed, and may be an area in which at least one component of the apparatus 1000 is disposed. The chamber CB may provide an alignment space of the light emitting elements LD and a drying processing space of the solvent SV. The chamber CB may have a circular structure, a quadrangular structure, or various shapes of structures.

In case that the inkjet printing apparatus 300 is disposed outside the chamber CB, the printing part PA may be disposed outside the chamber CB, and the target substrate SUB may be moved to the alignment part ALA after the ink I is printed on the target substrate SUB outside the chamber CB. However, the disclosure is not limited thereto.

In an embodiment, the inkjet printing apparatus 300 and the alignment part ALA may be disposed in a same area. For example, the inkjet printing apparatus 300 may be disposed inside the chamber CB in which the alignment part ALA is disposed. The printing part PA may be disposed inside the chamber CB, and the light emitting elements LD may be aligned after the ink I is printed on the target substrate SUB inside the chamber CB.

The transporting unit 700 may be disposed in the transporting part TA. The transporting unit 700 may move the target substrate SUB on which the printing process and the alignment process are completed from the alignment part ALA to the heat treatment part HA.

The heat treatment apparatus 900 may be disposed in the heat treatment part HA. The heat treatment apparatus 900 may generate heat on the target substrate SUB, thereby removing the solvent SV remaining on the target substrate SUB. The solvent SV sprayed onto the target substrate SUB may be removed by heat energy generated by the heat treatment apparatus 900.

The positions of the transporting part TA and the heat treatment part HA in the apparatus 1000 are not limited to a specific embodiment.

As described above, in the apparatus 1000, after the ink I is sprayed onto the target substrate SUB, using the inkjet printing apparatus 300 disposed in the printing part PA, the target substrate SUB may be moved to the alignment part ALA, and the alignment process of aligning the light emitting elements included in the ink I sprayed onto the target substrate SUB may be performed in the alignment part ALA.

The alignment process of the light emitting elements LD may be performed using the stage 110, the heating element 190, the electric field application module 100, the heat source part 500, and the vacuum pump 600. The display device DD in accordance with the disclosure may be characterized in that the light emitting elements LD may be aligned by drying at least a portion of the solvent SV while forming an electric field on the target substrate SUB in the same chamber CB.

The stage 110 may provide a space in which the target substrate SUB is disposed. For example, the target substrate SUB may be disposed on the stage 110. In an embodiment, the stage 110 may include an internal space in which the heating element 190 is disposed.

The heating element 190 may be disposed at at least one side of the stage 110. For example, the heating element 190 may be disposed in the internal space of the stage 110 to overlap the stage 110 in a plan view. However, the disclosure is not limited thereto. In another embodiment, the heating element 190 may be disposed outside the stage 110. For example, the heating element 190 may be disposed on the top of the stage 110. In another embodiment, the heating element 190 may be disposed on a side surface of the stage 110 or at a periphery of the stage 110. The position of the heating element 190 may be variously changed. However, for convenience, an embodiment that the heating element 190 is disposed inside the stage 110 is illustrated in the drawings.

The heating element 190 may include a heating material (e.g., a heat source). For example, the heating element 190 may include a hot plate as a heat source. The heating element 190 may radiate heat toward the stage 110. The heating element 190 may adjust (or control) a temperature of the stage 110 while the alignment process is performed. For example, the heating element 190 may include a heat source having a temperature in a range of about 20° C. to about 60° C., and the stage 110 may receive the heat transferred from the heating element 190, so that the temperature of the stage 110 may be adjusted in a range of about 20° C. to about 60° C.

An area of the heating element 190 may correspond to an area of the target substrate SUB in a plan view. For example, an area of a top surface of the heating element 190 and an area of a bottom surface of the target substrate SUB may be equal to each other. However, the disclosure is not limited thereto.

The heating element 190 may adjust a temperature of the target substrate SUB by adjusting a temperature of the stage 110. The heating element 190 may adjust the temperature of the target substrate, so that a temperature of the solvent SV sprayed onto the target substrate SUB can be indirectly adjusted. The viscosity of the solvent SV may vary according to the temperature of the solvent SV. Thus, the temperature of the solvent SV may be indirectly adjusted by adjusting the temperature of the target substrate SUB, using the heating element 190, and the viscosity of the solvent SV may be controlled. The light emitting elements LD placed in an electric field may be more readily rotated or moved as the viscosity of the solvent SV decreases, so that the alignment degree and orientation of the light emitting elements LD may be improved.

The electric field application module 100 may be disposed at a side of the stage 110 (e.g., on the top of an end portion of the stage 110), to form an electric field on the target substrate SUB in the alignment process. The electric field formed by the electric field application module 100 may be applied to the ink I sprayed onto the target substrate SUB. As the light emitting elements LD included in the ink I placed in the electric field are applied with the electric force, the orientation direction of the light emitting elements LD may be controlled. Therefore, the light emitting elements LD may be aligned in a direction on the target substrate SUB.

The heat source part 500 may apply heat to the ink I sprayed onto the target substrate SUB and dry at least a portion of the solvent SV, thereby improving the fixability of the light emitting elements LD on the target substrate SUB.

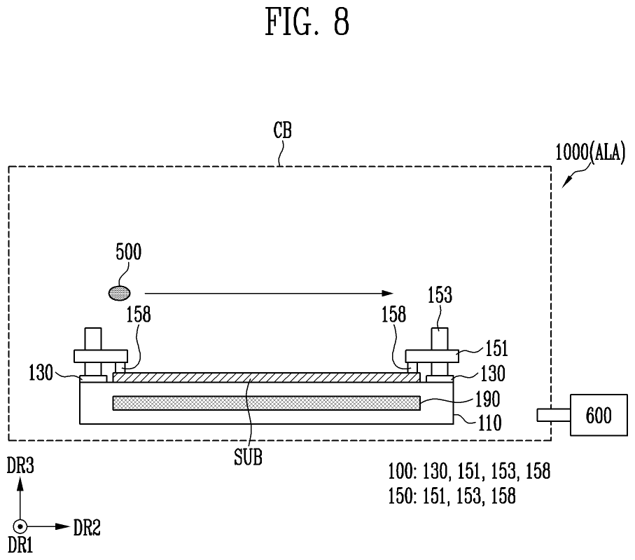

The vacuum pump 600 may control the pressure of an area in which the alignment process is performed while alignment process is performed. For example, the vacuum pump 600 may be connected to the chamber CB (see FIG. 8). The vacuum pump 600 may control the internal pressure of the chamber CB. For example, the vacuum pump 600 may form a reduced pressure atmosphere in the chamber CB such that an internal space of the chamber CB has a vacuum state. The vacuum pump 600 may reduce the pressure in the chamber CB.

In an embodiment, the vacuum pump 600 may be connected to the chamber CB through an exhaust line, and at least one of a pressure control valve and a flow control valve may be installed on the exhaust line. As the vacuum pump 600 exhausts a gas, the internal space of the chamber CB may form the vacuum state.

The vacuum pump 600 may control the pressure in the chamber CB (or form vacuum), thereby the fixability of the light emitting elements LD on the substrate SUB. For example, the vacuum pump 600 may form the vacuum in the chamber CB, thereby lowering a volatilization point of the solvent SV. As the volatilization point of the solvent SV is lowered, the solvent SV may be more readily evaporated, and at least a portion of the solvent SV may be dried.

FIG. 4 illustrates a schematic plan view in which a configuration of the apparatus 1000 in accordance with the embodiment of the disclosure is viewed from the top. FIG. 4 is a view for describing an arrangement relationship or operations of components included in the apparatus 1000 according to an embodiment, and the structure and arrangement of the apparatus 1000 are not limited to the embodiment of FIG. 4. In another embodiment, the apparatus 1000 may include additional members, and have a structure different from the structure shown in FIG. 4. Hereinafter, the configuration and operation of the apparatus 1000 will be described in detail with reference to other drawings in conjunction with FIG. 4.

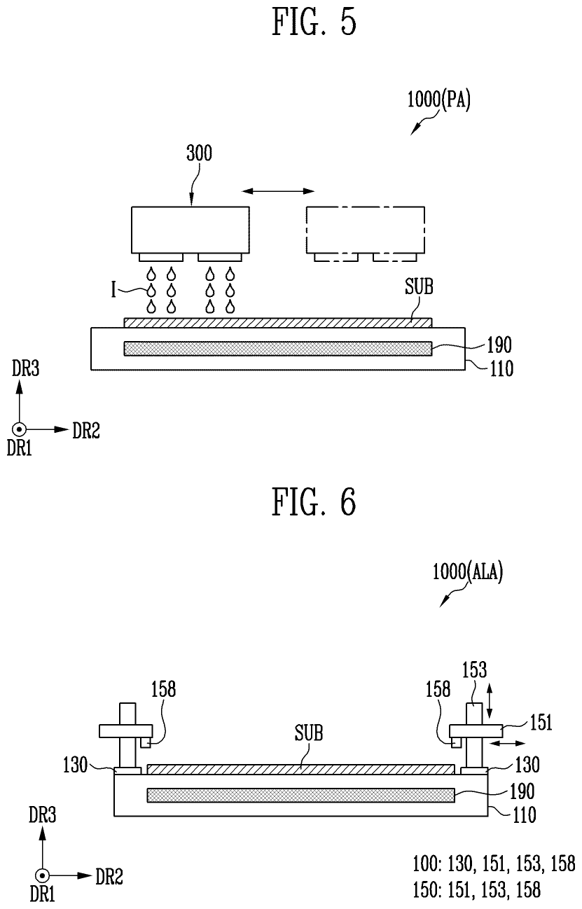

FIG. 5 is a schematic cross-sectional view illustrating an operation of the inkjet printing apparatus in accordance with an embodiment of the disclosure.

Referring to FIG. 5, the inkjet printing apparatus 300 may perform an operation of spraying the ink I onto the top of the target substrate SUB while moving parallel to a plane on which the target substrate SUB is disposed. For example, the inkjet printing apparatus 300 may spray the ink I onto the top of the target substrate SUB while moving in a direction (e.g., the first direction DR1 or the second direction DR2) in which the plane on which the target substrate SUB is disposed extends.

In an embodiment, as described above, the inkjet printing apparatus 300 may be disposed outside the chamber CB to which the vacuum pump 600 is connected, and the printing process may be performed outside the chamber CB. However, the disclosure is not limited thereto. In another embodiment, the inkjet printing apparatus 300 may be disposed inside the chamber CB to which the vacuum pump 600 is connected, and the printing process may be performed inside the chamber CB.

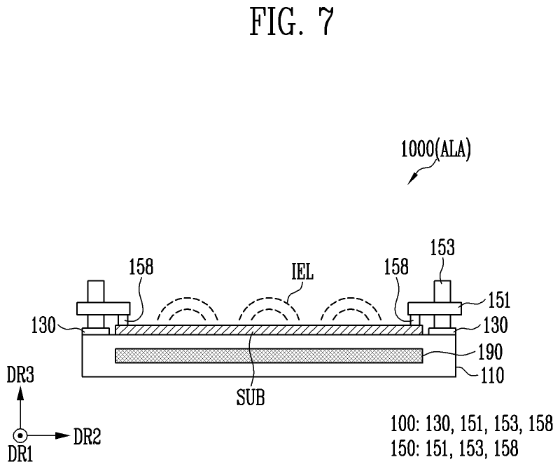

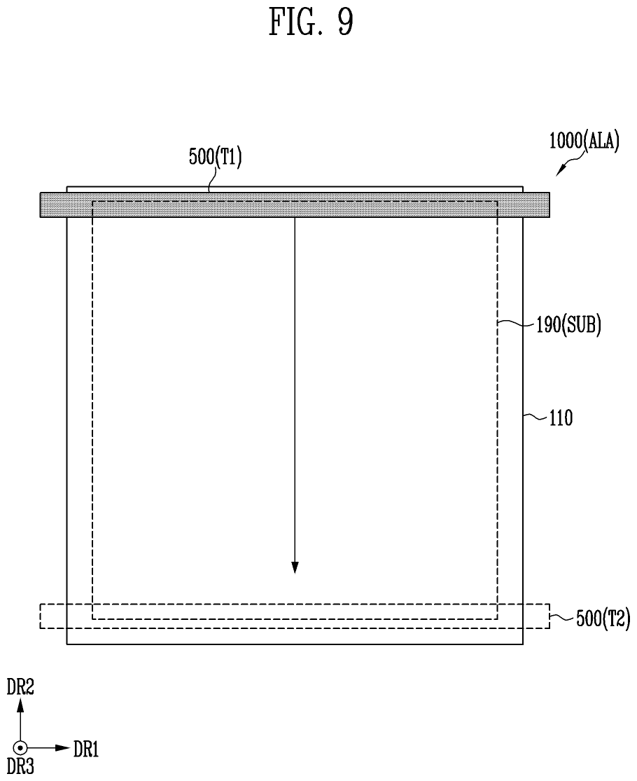

FIGS. 6 and 7 are schematic cross-sectional views illustrating an operation of the electric field application module in accordance with an embodiment of the disclosure. FIG. 6 is a schematic cross-sectional view illustrating a first state in which no electric field is formed on the target substrate SUB. FIG. 7 is a schematic cross-sectional view illustrating a second state in which an electric field is formed on the target substrate SUB. In FIGS. 6 and 7, configurations of the heat source part 500 and the vacuum pump 600 are not illustrated to illustrate the operation of the electric field application module 100. Operations of the heat source part 500 and the vacuum pump 600 will be described below with reference to FIGS. 8 and 9.

Referring to FIGS. 6 and 7, the stage 110 may provide a space in which the target substrate SUB is disposed. The stage 110 may support members included in the electric field application module 100.

An overall shape of the stage 110 may correspond to a shape of the target substrate SUB in a plan view. For example, in case that the target substrate SUB has a rectangular shape in a plan view, the stage 110 may have a rectangular shape. In case that the target substrate SUB has a circular shape in a plan view, the stage 110 may have a circular shape. However, the disclosure is not limited thereto.

The electric field application module 100 may be disposed at a side of the stage 110. For example, the electric field application module 100 may be disposed on the stage 110. The electric field application module 100 may include a probe support 130 and a probe unit 150. The probe support 130 and the probe unit 150 may be disposed on the stage 110.

The probe support 130 may provide a space in which the probe unit 150 is disposed on the stage 110. For example, the probe support 130 may be disposed at at least one side on the stage 110, and extend in a direction that the side portion extends. In an embodiment, the probe support 130 may be disposed at a side and another side in the second direction DR2 (e.g., upper and lower sides in a plan view) on the stage 110, and extend in the first direction DR1. However, the disclosure is not limited thereto, and the structure of the probe support 130 may vary according to a number of probe units 150 included in the electric field application module 100, an arrangement or structure of the probe units 150, or the like.

The probe unit 150 may be disposed on the probe support 130. The probe unit 150 may form an electric field on the target substrate SUB provided on the stage 110. Like the probe support 130, the probe unit 150 may extend in a direction, e.g., the first direction DR1.

The probe unit 150 may include a probe driver 153, a probe jig 151 disposed on the probe driver 153 such that an electrical signal is transferred thereto, and a probe pad 158 connected to the probe jig 151 to transfer an electrical signal to the target substrate SUB.

The probe driver 153 may be disposed on the probe support 130 to move the probe jig 151 and the probe pad 158. For example, the probe driver 153 may move the probe jig 151 in a horizontal direction and a vertical direction, e.g., a horizontal direction (e.g., the second direction DR2 (or the first direction DR1)) as a direction parallel to the plane on which the target substrate SUB is disposed extends and a vertical direction (e.g., the third direction DR3) which is perpendicular to the plane on which the target substrate SUB is disposed. The probe pad 158 may be connected to or separated from the target substrate SUB by driving of the probe driver 153.

The probe pad 158 may form an electric field on the target substrate SUB through an electrical signal transferred from the probe jig 151. The probe pad 158 may be connected to the target substrate SUB to transfer an electrical signal to the target substrate SUB, thereby forming an electric field on the target substrate SUB. In an embodiment, the probe pad 158 may contact an electrode or a power pad of the target substrate SUB, and the electrical signal of the probe jig 151 may be transferred to the electrode or the power pad. The electrical signal transferred to the target substrate SUB may form an electric field on the target substrate SUB. However, the disclosure is not limited thereto, and the probe pad 158 may be a member which forms an electric field through the electrical signal transferred from the probe jig 151 without contacting the target substrate SUB.

In the first state of FIG. 6, the probe unit 150 may be disposed on the probe support 130 to be spaced apart from the target substrate SUB. The probe driver 153 of the probe unit 150 may drive in the second direction DR2 (or the first direction DR1) as the horizontal direction and the third direction DR3 as the vertical direction, thereby allowing the probe pad 158 to be spaced apart from the target substrate SUB. The probe pad 158 may be spaced apart from the target substrate SUB such that no electric field is formed on the target substrate SUB.

In the second state of FIG. 7, the probe driver 153 of the probe unit 150 may drive, thereby electrically connecting the probe pad 158 to the target substrate SUB. The probe driver 153 of the probe unit 150 may drive in the second direction DR2 (or the first direction DR1) as the horizontal direction and the third direction DR3 as the vertical direction, thereby allowing the probe pad 158 to contact the target substrate SUB. The probe jig 151 of the probe unit 150 may transfer an electrical signal to the probe pad 153, and an electric field IEL may be formed on the target substrate SUB through the probe pad 158.

In the drawings, it is illustrated that two probe units 150 are disposed at sides of the stage 110 and are simultaneously connected to the target substrate SUB. However, the disclosure is not limited thereto. In another embodiment, multiple probe units 150 may be individually driven. For example, the probe units 150 may be simultaneously driven to form an electric field on the target substrate SUB, or be sequentially driven to form the electric field on the target substrate SUB.

The electric field application module 100 of the apparatus 1000 may perform an operation of forming the electric field IEL on the target substrate SUB by driving the probe driver 153 while the alignment process of the light emitting elements LD is performed after the ink I is sprayed onto the target substrate SUB, and separate the probe pad 158 from the target substrate SUB by re-driving the probe driver 153 in a process after the alignment process.

FIG. 8 is a schematic cross-sectional view illustrating an operation of the heat source part in accordance with an embodiment of the disclosure. FIG. 9 is a schematic plan view of the heat source part in accordance with an embodiment of the disclosure. FIG. 9 is a plan view illustrating a schematic arrangement of the heat source part 500, the stage 110, and the target substrate SUB.

Referring to FIGS. 8 and 9, the heat source part 500 may be disposed in the camber CB. The heat source part 500 may be disposed on the stage 110 and the target substrate SUB. The heat source part 500 may be disposed on the target substrate SUB on which an electric field is formed, and apply heat to the target substrate SUB. The heat source part 500 may include a heat source, and apply thermal energy to the target substrate SUB.

In an embodiment, the heat source part 500 may include, as a heat source, a hot plate, an oven, a High Voltage Direct current (HVDC) irradiation apparatus, an Infrared Radiation (IR) irradiation apparatus, or the like. However, the disclosure is not limited thereto.

The heat source part 500 may include a bar-like heat source. For example, the heat source part 500 may have a bar shape extending in the first direction DR1. For example, the heat source part 500 may have a rectangular shape having short sides in the second direction DR2 and long sides in the first direction DR1 in a plan view. However, the disclosure is not limited thereto, and the heat source part 500 may have a quadrangular shape other than the rectangular shape in a plan view.

In an embodiment, the heat source part 500 may include a bar-like heating lamp. For example, the heat source part 500 may include a lamp including a filament inside a bar-like tube which has the vacuum state or has a gas injected.

The heat source of the heat source part 500 may have a temperature in a range of about 60° C. to about 200° C. As the heat source of the heat source part 500 has the temperature in a range of about 60° C. to about 200° C., the solvent SV may be effectively evaporated or dried.

The heat source part 500 may move on the target substrate SUB. The heat source part 500 may move parallel to a plane on which the target substrate SUB is disposed. The heat source part 500 may move along a direction (e.g., the second direction DR2) in which the plane on which the target substrate SUB is disposed extends. For example, the heat source part 500 may move along a direction other than a direction (e.g., the first direction DR1) in which the heat source part 500 extends. For example, the heat source part 500 may move along a direction (e.g., the second direction DR2) perpendicular to the direction (e.g., the first direction DR1) in which the heat source part 500 extends. However, the disclosure is not limited thereto. The heat source part 500 may move along the first direction DR1, and move along the direction (e.g., the third direction DR3) perpendicular to the plane on which the target substrate SUB is disposed. Hereinafter, for convenience, an embodiment that the heat source part 500 moves along the second direction DR2 among the directions in which the plane on which the target substrate SUB is disposed extends will be described.

The heat source part 500 may reciprocate parallel to the plane on which the target substrate SUB is disposed. For example, the heat source part 500 may reciprocate along the direction (e.g., the second direction DR2) parallel to the plane on which the target substrate SUB is disposed extends.

At a first time T1, the heat source part 500 may overlap a first side (e.g., a left end portion in FIG. 8) of the stage 110 or the target substrate SUB in a plan view, and may not overlap a second side (e.g., a right end portion in FIG. 8) of the stage 110 or the target substrate SUB in a plan view.

In a period between the first time T1 and a second time T2 after the first time T1, the heat source part 500 may move on the stage 110 (or the target substrate SUB). After the first time T1, the heat source part 500 may move along the direction (e.g., the second direction DR2) parallel to the plane on which the target substrate SUB is disposed extends. At the second time T2, the heat source part 500 may not overlap the first side (e.g., a left end portion) of the stage 110 or the target substrate SUB in a plan view, and may overlap the second side (e.g., a right end portion) of the stage 110 or the target substrate SUB in a plan view.

As the heat source part 500 includes a bar-like heat source and moves on the target substrate SUB, the solvent SV disposed on the target substrate SUB may be locally heated. Accordingly, the heat source part 500 may effectively remove the solvent SV, and minimize a temperature change of the stage 100 and the target substrate SUB.

In case that the temperature of the stage 110 is excessively increased (e.g., exceeding 60° C.), the solvent SV may be dried before the light emitting elements LD are properly aligned, and therefore, the light emitting elements LD may not be rotated in the solvent SV, and the light emitting elements LD may not be properly aligned. In the apparatus 1000 in accordance with the disclosure, the heat source part 500 may locally heat the target substrate SUB, thereby drying the solvent SV at an appropriate time while not having influence on the temperature of the stage 110 and the target substrate SUB.

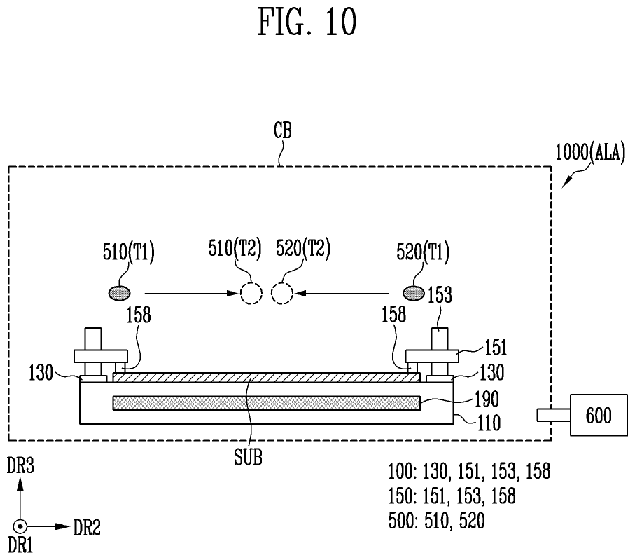

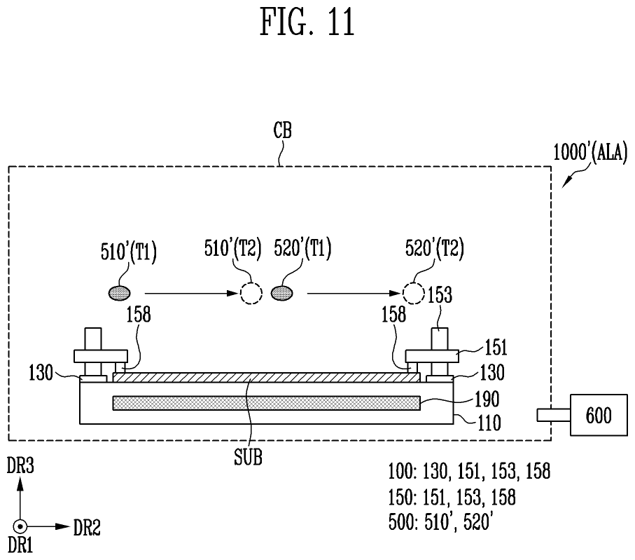

FIGS. 10 and 11 are schematic cross-sectional views illustrating apparatuses for manufacturing a display device in accordance with embodiments of the disclosure. Apparatuses 1000 and 1000 shown in FIGS. 10 and 11 may be different from the apparatus 1000 shown in FIG. 8, at least in that the heat source part 500 is formed in plurality.

Referring to FIG. 10, the heat source part 500 may include a first heat source part 510 and a second heat source part 520.

The first heat source part 510 and the second heat source part 520 may not overlap each other in a plan view. The first heat source part 510 and the second heat source part 520 may be disposed on the stage. For example, the first heat source part 510 may be disposed to overlap the first side (e.g., the left end portion) of the stage 110 or the target substrate SUB in a plan view, and the second heat source part 520 may be disposed to overlap the second side (e.g., the right end portion) of the stage 110 or the target substrate SUB in a plan view.

The first heat source part 510 and the second heat source part 520 may move on the target substrate SUB. The first heat source part 510 and the second heat source part 520 may move on the plane on which the target substrate SUB is disposed. The first heat source part 510 and the second heat source part 520 may move along the direction (e.g., the second direction DR2) parallel to the plane on which the target substrate SUB is disposed extends.

The first heat source part 510 and the second heat source part 520 may reciprocate on the plane on which the target substrate SUB is disposed. For example, the first heat source part 510 and the second heat source part 520 may reciprocate along the direction (e.g., the second direction DR2) parallel to the plane on which the target substrate SUB is disposed extends.

The first heat source part 510 and the second heat source part 520 may move along different directions on a line during a same time period. For example, while the first heat source part 510 moves in the second direction DR2, the second heat source part 520 may move in a direction opposite to the second direction DR2.

At a first time T1, the first heat source part 510 may overlap the first side (e.g., the left end portion) of the stage 110 in a plan view, and the second heat source part 520 may overlap the second side (e.g., the right end portion) of the stage 110 in a plan view. At the first time T1, the first heat source part 510 and the second heat source part 520 may not overlap a third side (e.g., a central area) of the stage 110 in a plan view. The central area of the stage 110 may be an area corresponding to a central portion in case that the stage 110 is divided into three portions along the second direction DR2 in a plan view.

In a period between the first time T1 and a second time T2 after the first time T1, the first heat source part 510 and the second heat source part 520 may move on the stage 110 (or the target substrate SUB). After the first time T1, each of the first heat source part 510 and the second heat source part 520 may move toward an area overlapping the third side (e.g., the central area) of the stage 110 in a plan view. For example, after the first time T1, the first heat source part 510 may move along the second direction DR2, and the second heat source part 520 may move along the direction opposite to the second direction DR2.

At the second time T2, the first heat source part 510 may not overlap the first side (e.g., the left end portion) of the stage 110 in a plan view, and the second heat source part 520 may not overlap the second side (e.g., the right end portion) of the stage 110 in a plan view.

Referring to FIG. 11, in an embodiment, a first heat source part 510′ and a second heat source part 520′ may move along a same direction on a line in a same time period. For example, the first heat source part 510′ and the second heat source part 520′ may move along the second direction DR2.

The first heat source part 510′ may be disposed to overlap the first side (e.g., the left end portion) of the stage 110 or the target substrate SUB in a plan view, and the second heat source part 520′ may be disposed to overlap the third side (e.g., the central area) of the stage 110 or the target substrate SUB in a plan view.

At a first time T1, the first heat source part 510′ may overlap the first side (e.g., the left end portion) of the stage 110 in a plan view, and the second heat source part 520′ may overlap the third side (e.g., the central area) of the stage 110 in a plan view. However, the disclosure is not limited thereto.

In a period between the first time T1 and a second time T2 after the first time T1, the first heat source part 510′ and the second heat source part 520′ may move on the stage 110 (or the target substrate SUB). The first heat source part 510 may move along the second direction DR2 toward an area overlapping the third side (e.g., the central area) of the stage 110 in a plan view. At the second time T2, the first heat source part 510′ may not overlap the first side (e.g., the left end portion) of the stage 110 in a plan view, and may overlap the third side (e.g., the central area) of the stage 110 in a plan view.

At the second time T2, the second heat source part 520′ may move along the second direction DR2 toward an area overlapping the second side (e.g., the right end portion) of the stage 110 in a plan view. At the second time T2, the second heat source part 520′ may not overlap the third side (e.g., the central area) of the stage 110 in a plan view, and may overlap the second side (e.g., the right end portion) of the stage in a plan view.

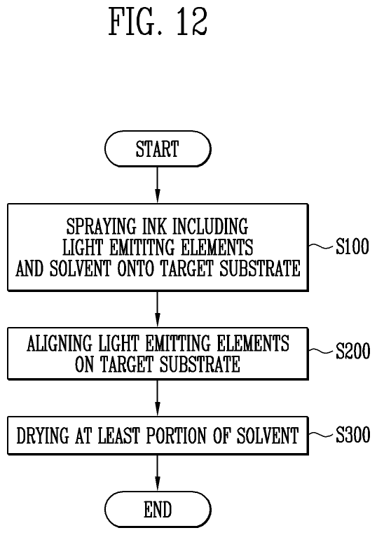

Hereinafter, a method of manufacturing the display device DD will be described with reference to FIGS. 12 to 15. FIG. 12 is a flowchart illustrating a method of manufacturing a display device. FIGS. 13 to 15 are schematic cross-sectional views illustrating processes of manufacturing a display device.

Referring to FIG. 12, a method of manufacturing the display device DD may include a step of spraying an ink including light emitting elements and a solvent onto a target substrate, a step S200 of aligning the light emitting elements on the target substrate, and a step S300 of drying at least a portion of the solvent.

Referring to FIG. 13, before the step S100 of spraying the ink including the light emitting elements and the solvent onto the target substrate, a target substrate SUB may be prepared. In an embodiment, a pixel circuit layer including a pixel circuit for driving light emitting elements LD may be formed on the target substrate SUB. The pixel circuit layer may include conductive layers and insulating layers disposed between the conductive layers. For example, as shown in FIG. 13, a first electrode 21 and a second electrode 22, which are used to drive the light emitting elements LD, may be formed on the target substrate SUB.

In an embodiment, the first electrode 21 may be an anode electrode, and the second electrode 22 may be a cathode electrode. However, the disclosure is not limited thereto. In another embodiment, the first electrode 21 may be the cathode electrode, and the second electrode 22 may be the anode electrode.

Referring to FIG. 14, the step S100 of spraying the ink including the light emitting elements and the solvent onto the target substrate may include a step of spraying, by the inkjet printing apparatus 300, an ink I.

The ink I may include light emitting elements LD and a solvent SV. The light emitting elements LD may be dispersed in the solvent SV.

The ink I may be discharged through a nozzle NZ of the inkjet printing apparatus 300 and sprayed onto the first electrode 21 and the second electrode 22, which are disposed on the target substrate SUB.

In an embodiment, the step S100 of spraying the ink including the light emitting elements and the solvent onto the target substrate may be performed together with the step S200 of aligning the light emitting elements on the target substrate and the step S300 of drying the at least a portion of the solvent in the same chamber CB or in different spaces.

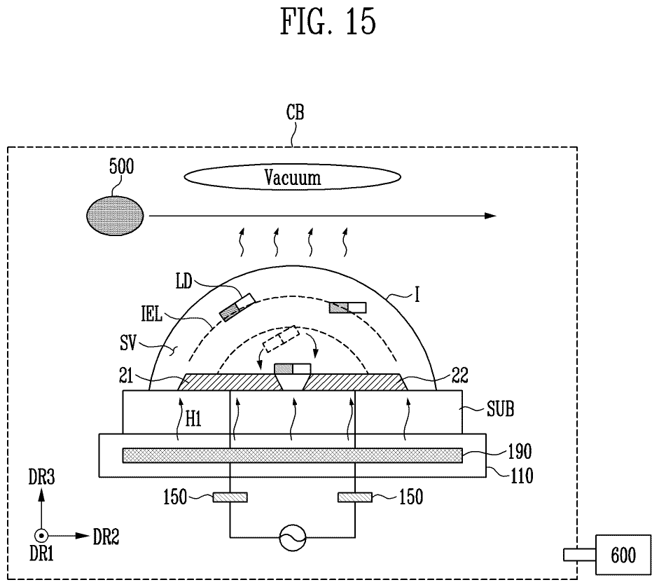

Referring to FIG. 15, after the step S100 of spraying the ink including the light emitting elements and the solvent onto the target substrate, the step S200 of aligning the light emitting elements on the target substrate and the step S300 of drying the at least a portion of the solvent may be performed.

The step S200 of aligning the light emitting elements on the target substrate and the step S300 of drying the at least a portion of the solvent may be performed in the same chamber CB.

The step S200 of aligning the light emitting elements on the target substrate may include a step of forming an electric field IEL on the target substrate SUB. The light emitting elements LD may be aligned by the electric field IEL. For example, the light emitting elements LD may be disposed between the first electrode 21 and the second electrode 22 by a dielectrophoretic force.

As described above, the electric field IEL may be formed on the target substrate SUB, using the probe unit 150. The probe unit 150 may apply an electrical signal to the first electrode 21 and the second electrode 22. The probe unit 150 may be connected to a pad (not shown) provided on the target substrate SUB, and apply the electrical signal to the first electrode 21 and the second electrode 22, which are connected to the pad. In case that the probe unit 150 applies an electrical signal to the first electrode 21 and the second electrode 22, the electric field IEL may be formed between the first electrode 21 and the second electrode 22. A dielectrophoretic force caused by the electric field IEL may act on the light emitting elements LD. By the dielectrophoretic force, the light emitting elements LD may be disposed between the first electrode 21 and the second electrode 22 while the orientation direction and position of the light emitting elements LD are changed.

The step S200 of aligning the light emitting elements on the target substrate may include a step of controlling a temperature of the target substrate SUB. The step of controlling the temperature of the target substrate SUB may be simultaneously performed with the step of forming the electric field IEL on the target substrate SUB.

The step of controlling the temperature of the target substrate SUB may include a step of applying heat to the target substrate SUB, using the heating element 190. The heating element 190 may control the temperature of the target substrate SUB by applying heat to the target substrate SUB while the light emitting elements LD are aligned. The heating element 190 may control a temperature of the solvent SV. As the temperature of the solvent SV is controlled, the heating element 190 may enable the light emitting elements LD to be readily moved or rotated, and accordingly, the alignment degree of the light emitting elements LD may be improved.

The heating elements 190 may enable the light emitting elements LD to be readily moved or rotated by increasing the temperature of the solvent SV, and prevent the temperature of the solvent SV from increasing to a certain temperature range or more. For example, the heating element 190 may control the stage 110 to have a temperature in a range of about 20° C. to about 60° C. Accordingly, the heating element 190 may prevent the solvent SV from being completely dried before the light emitting elements LD are aligned.

After the light emitting elements LD are aligned by forming the electric field IEL, using the probe unit 150, the step S300 of drying the at least a portion of the solvent may be performed.

The step S300 of drying the at least a portion of the solvent may include a step of moving the heat source part 500 on the target substrate SUB. In the step of moving the heat source part 500 on the target substrate SUB, the heat source part 500 may move along a direction (e.g., the second direction DR2) parallel to a plane on which the target substrate SUB is disposed extends. Hereinafter, an operation of the heat source part 500 has been described above, and therefore, descriptions of overlapping portions will be omitted.

The apparatus 1000 may locally heat the solvent SV. Accordingly, the heat source part 500 may minimize a temperature change of the stage 110 and the target substrate SUB, and effectively dry the solvent SV at an appropriate time.

While the step S300 of drying the at least a portion of the solvent is performed, vacuum of the chamber CB may be maintained by the vacuum pump 600. The step S300 of drying the at least a portion of the solvent may include a step of forming an internal space of the chamber CB in a vacuum state as the vacuum pump 600 is connected to the chamber CB. While the step S300 of drying the at least a portion of the solvent is performed, the vacuum pump 600 may reduce pressure in the chamber CB, thereby forming the internal space of the chamber CB to be in the vacuum state.

A volatilization point of the solvent SV may be lowered by the vacuum pump 600, and at least a portion of the solvent SV may be dried as the solvent SV is more readily evaporated.

In an embodiment, after step S300 of drying the at least a portion of the solvent is performed, the target substrate SUB may be further moved to the heat treatment part HA by the transporting part TA, and additional components such as an insulating layer may be further manufactured after the solvent SV is dried.

In accordance with the disclosure, an apparatus for manufacturing a display device and a method of manufacturing a display device may improve an alignment degree of light emitting elements.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. An apparatus for manufacturing a display device, the apparatus comprising:
a chamber;
a stage supporting a target substrate;
an electric field application module disposed at a side of the stage;
a heating element overlapping the stage in a plan view;
a heat source part that moves in a direction parallel to a plane the stage extends on the stage; and
a vacuum pump connected to the chamber.

2. The apparatus of claim 1, further comprising:
a printing part that sprays an ink including at least one light emitting element onto the target substrate,
wherein the electric field application module forms an electric field on the target substrate, such that the at least one light emitting element is aligned on the target substrate.

3. The apparatus of claim 1, wherein
the stage includes an internal space in which the heating element is disposed, and
the heating element is disposed in the internal space.

4. The apparatus of claim 3, wherein the heating element includes a hot plate.

5. The apparatus of claim 3, wherein the heating element includes a heat source having a temperature in a range of about 20° C. to about 60° C.

6. The apparatus of claim 1, wherein
the heat source part includes a bar-shaped heat source extending in a first direction, and
the heat source part moves in the direction other than the first direction.

7. The apparatus of claim 1, wherein
the heat source part moves on the stage between a first time and a second time after the first time, and,
at the first time,
the heat source part overlaps a first side of the stage in a plan view, and
the heat source part does not overlap a second side of the stage in a plan view.

8. The apparatus of claim 7, wherein, at the second time,
the heat source part does not overlap the first side of the stage in a plan view, and
the heat source part overlaps the second side of the stage in a plan view.

9. The apparatus of claim 1, wherein
the heat source part includes a first heat source part and a second heat source part,
the first heat source part and the second heat source part move on the stage between a first time and a second time after the first time,
at the first time, the first heat source part overlaps a first side of the stage in a plan view, and
at the first time, the second heat source part overlaps a second side of the stage in a plan view.

10. The apparatus of claim 1, wherein
the heat source part includes a first heat source part and a second heat source part,
the first heat source part and the second heat source part move on the stage between a first time and a second time after the first time,
at the first time, the first heat source part overlaps an end portion of the stage in a plan view,
at the first time, the second heat source part overlaps a central area of the stage in a plan view, and
between the first time and the second time, the first heat source part and the second heat source part move in a same direction.

11. The apparatus of claim 1, wherein the heat source part is disposed in the chamber.

12. The apparatus of claim 1, wherein the heat source part includes a heat source having a temperature in a range of about 60° C. to about 200° C.

13. The apparatus of claim 1, wherein
the vacuum pump is connected to the chamber through an exhaust line,
at least one of a pressure control valve and a flow control valve is installed on the exhaust line, and
the vacuum pump forms a vacuum pressure atmosphere in the chamber.

14. The apparatus of claim 1, wherein
the electric field application module includes a probe support and a probe unit, which are disposed on the stage,
the probe unit includes:
a probe driver;
a probe jig disposed on the probe driver such that an electrical signal is transferred to the prove jig; and
a probe pad transferring the electrical signal to the target substrate, and
the probe driver moves the probe jig in a horizontal direction and a vertical direction.

15. The apparatus of claim 2, wherein the ink further includes a solvent.

16. A method of manufacturing a display device, the method comprising:
spraying an ink including at least one light emitting element and a solvent onto a target substrate;
aligning the at least one light emitting element on the target substrate; and
drying at least a portion of the solvent, wherein
the aligning of the at least one light emitting element includes:
forming an electric field on the target substrate; and
controlling a temperature of the target substrate,
the drying of the at least a portion of the solvent includes moving a heat source part on the target substrate, and
the aligning of the at least one light emitting element and the drying of the at least a portion of the solvent are performed in a chamber.

17. The method of claim 16, wherein
the forming of the electric field on the target substrate and the controlling of the temperature of the target substrate are simultaneously performed, and
the controlling of the temperature of the target substrate includes applying heat to the target substrate, using a heating element.

18. The method of claim 16, wherein
the moving of the heat source part includes allowing the heat source part to reciprocate along a direction parallel to a plane the target substrate extends on the target substrate, and
the heat source part includes a bar-shaped heat source extending in a first direction.

19. The method of claim 16, wherein the drying of the at least a portion of the solvent includes forming an internal space of the chamber to be in a vacuum state as a vacuum pump is connected to the chamber.

20. The method of claim 16, wherein
the forming of the electric field on the target substrate includes forming an electric field, using a probe unit,
the probe unit includes:
a probe driver;
a probe jig disposed on the probe driver such that an electrical signal is transferred to the probe jig; and
a probe pad transferring the electrical signal to the target substrate, and
the probe driver moves the probe jig in a horizontal direction and a vertical direction.
